(19) United States
(12) Patent Application Publication
(10) Pub. No.: US 2025/0300039 A1
(43) Pub. Date: Sep. 25, 2025

(54) Electronic Devices Including Phase-Change Materials

(71) Applicant: The Government of the United States of America, as represented by the Secretary of the Navy, Arlington, VA (US)

(72) Inventors: Francis J. Kub, Arnold, MD (US); Karl D. Hobart, Alexandria, VA (US); Travis J. Anderson, Gainesville, FL (US); Andrew D. Koehler, Alexandria, VA (US)

(73) Assignee: The Government of the United States of America, as represented by the Secretary of the Navy, Arlington, VA (US)

(21) Appl. No.: 19/085,538

(22) Filed: Mar. 20, 2025

Related U.S. Application Data
(60) Provisional application No. 63/568,090, filed on Mar. 21, 2024.
(60) Provisional application No. 63/568,069, filed on Mar. 21, 2024.

(51) Int. Cl. H01L 23/427

(52) U.S. Cl. CPC H01L 23/427

(57) ABSTRACT

According to some embodiments disclosed herein, an electronic device includes a semiconductor electronic substrate and a phase-change material thermally and mechanically coupled with the semiconductor electronic substrate. The phase-change material undergoes a phase-change at a phase-change temperature for the phase-change material. Moreover, the phase-change temperature is less than a peak operating temperature of the electronic device.

### CROSS-REFERENCE TO RELATED APPLICATIONS

This Application is a Nonprovisional Utility Patent Application and claims the benefit of priority under 35 U.S.C. Sec. 119 based on U.S. Provisional Patent Application No. 63/568,090 filed on Mar. 21, 2024, and based on U.S. Provisional Patent Application No. 63,568,069 filed Mar. 21, 2024. The disclosures of Provisional Application No. 63/568,090, Provisional Application No. 63/568,069, and all references cited herein are hereby incorporated in their entirety by reference into the present disclosure.

### FEDERALLY SPONSORED RESEARCH AND DEVELOPMENT

The United States Government has ownership rights in this invention. Licensing inquiries may be directed to Office of Technology Transfer, US Naval Research Laboratory, Code 1004, Washington, D.C. 20375, USA; +1.202.767.7230; nrltechtran@us.navy.mil, referencing Navy Case #211174-US2.

### TECHNICAL FIELD

The present disclosure relates to electronics, and more particularly to structures and methods providing temperature control for electronic devices.

### BACKGROUND OF THE INVENTION

High-speed and/or high-power semiconductor electronic devices may generate heat during operation, and failure to provide sufficient cooling for such devices may reduce performance and/or reliability thereof. Accordingly, there continues to exist a need for improved methods and/or structures to temperature control for semiconductor electronic devices.

### SUMMARY OF THE INVENTION

This summary is intended to introduce in simplified form, a selection of concepts that are further described in the Detailed Description. This summary is not intended to identify key or essential features of the claimed subject matter, nor is it intended to be used as an aid in determining the scope of the claimed subject matter. Instead, it is merely presented as a brief overview of the subject matter described and claimed herein.

According to some embodiments of inventive concepts, an electronic device includes a semiconductor electronic substrate, and a phase-change material thermally and mechanically coupled with the semiconductor electronic substrate. More particularly, the phase-change material undergoes a phase-change at a phase-change temperature for the phase-change material, and the phase-change temperature is less than a peak operating temperature of the electronic device.

### BRIEF DESCRIPTION OF DRAWINGS

Examples of embodiments of inventive concepts may be more clearly understood from the following detailed description taken in conjunction with the accompanying drawings in which:

FIG. 1 is a cross-sectional view illustrating a semiconductor electronic device with a phase-change material and an encapsulation structure thereon according to some embodiments of inventive concepts;

FIG. 2A is a cross-sectional view illustrating the semiconductor electronic device of FIG. 1 coupled with a packaging substrate through a phase-change material and an encapsulation structure according to some embodiments of inventive concepts;

FIG. 2B is a top view of the phase-change material and encapsulation structure of FIG. 2A according to some embodiments of inventive concepts;

FIG. 3 is cross-sectional view illustrating a semiconductor electronic device with a metallic airbridge, a phase-change material, and an encapsulation structure according to some embodiments of inventive concepts;

FIG. 4 is a cross-sectional view illustrating a semiconductor electronic device with a metallic airbridge, a first phase-change material, and a first encapsulation structure, that is coupled with a packaging substrate through a second phase-change material and a second encapsulation structure;

FIG. 5 is a cross-sectional view illustrating a semiconductor electronic device thermally coupled with a phase-change material through a bonding layer and a substrate according to some embodiments of inventive concepts;

FIG. 6 is a cross-sectional view illustrating semiconductor electronic device with a metallic air bridge, a first phase-change material, and a first encapsulation material on a first side, and with a second phase-change material and a second encapsulation material on a second side, according to some embodiments of inventive concepts; and

FIG. 7 is a cross-sectional view illustrating a semiconductor electronic device with a phase-change material and a polymer encapsulation structure thereon according to some embodiments of inventive concepts.

### DETAILED DESCRIPTION OF THE INVENTION

Aspects and features of the present disclosure will now be described more fully with reference to the accompanying drawings. The following description shows, by way of example, combinations and configurations in which aspects, features, and embodiments of inventive concepts can be put into practice. It will be understood that the disclosed aspects, features, and/or embodiments are merely examples, and that one skilled in the art may use other aspects, features, and/or embodiments or make functional and/or structural modifications without departing from the scope of the present disclosure. Moreover, like reference numerals refer to like elements throughout, and sizes of each of the elements may be exaggerated for clarity and conveniences of explanation.

A thermal buffer can increase a thermal capacity of an electronic device and can reduce a peak temperature of the electronic device.

The present disclosure describes methods and electronic device structures that incorporate phase-change materials with semiconductor electronic devices according to some embodiments of inventive concepts.

According to some embodiments, a phase-change material is deposited/grown on or adhered to an electrically conductive electrode and/or a substrate of a semiconductor electronic device. The phase-change material may undergo a solid-to-liquid phase-change and/or a solid-to-solid phase-change in response to heating to/above a phase-change temperature for the phase-change material. In the case of solid-to-liquid phase-change, the phase-change material may optionally be encapsulated within an encapsulation material/structure that remains solid above the phase-change temperature for the phase-change material (and above a peak operating temperature of the semiconductor electronic device). The encapsulation structure may be a metal structure formed using an encapsulation material such as an electroless/electroplated metal layer formed by deposition, a nanostructured silver layer formed by deposition, a nanostructured material layer formed by deposition, a material layer formed by chemical vapor deposition (CVD), a polymer, or other suitable material.

In some embodiments, the semiconductor electronic device may include a semiconductor electronic substrate having opposing front and back sides with at least one electronic device including one or more doped regions (i.e., n-type and/or p-type doped regions) on the front side of the semiconductor electronic substrate. The semiconductor electronic device, for example, may include one or more of a Field Effect Transistor (FET), an Insulated Gate Bipolar Transistor (IGBT), a Thyristor, a P-type/intrinsic/N-type (PiN) diode, a Power Switch, a microwave device, a radio frequency (RF) device, CMOS circuity, and/or an integrated circuit (IC) device. The electronic device may include a plurality of electrically conductive electrodes coupled with the semiconductor electronic device, and the electrodes may include one or more of a source electrode(s), a drain electrode(s), a gate electrode(s), an anode electrode(s), a cathode electrode(s), an emitter electrode(s), a collector electrode(s), or a base electrode(s). Each electrically conductive electrode may include a metal, a metal alloy, a silicide, polysilicon, a metal oxide, a metal airbridge, a solder, a solder alloy, a nanostructured metal, a nanostructured silver, an electroplated metal, an electroless deposited metal, and/or other conductive material. If the semiconductor electronic device is a lateral device, all electrodes may be on the front side of the semiconductor electronic substrate. If the electronic device is a vertical device or if the electronic device is a lateral device with a through substrate via, one or more of the electrodes may be on the back side of the semiconductor electronic substrate.

The phase-change material may optionally be formed on a first portion (also referred to as a covered region/portion) of an electrically conductive electrode, and a second portion (also referred to as an exposed region/portion) of the electrically conductive electrode may be devoid/free of the phase-change material. For example, the second portion of the electrically conductive electrode surface may be devoid/free of the phase-change material to facilitate an electrical connection such as a wire bond, a flip-chip solder bond, a wedge bond, or other electrical connection structure/method known to those skilled in the art.

According to some embodiments, the phase-change material may be formed within a solder or nanostructured silver layer that connects the device to a substrate or to a flip-chip substrate.

According to some embodiments, the phase-change material may have a selected thermal conductivity, linear thermal expansion coefficient, modulus, and electrical conductivity.

According to some embodiments of inventive concepts, a phase-change material is integrated with a semiconductor electronic device. The phase-change material provides a high thermal capacity during a phase-change. Accordingly, thermal energy that would otherwise go into raising the temperature of the electronic device will instead go into the phase-change (e.g., melting) of the phase-change material. Thus, a peak temperature of the electronic device may be reduced, thereby improving reliability of the electronic device.

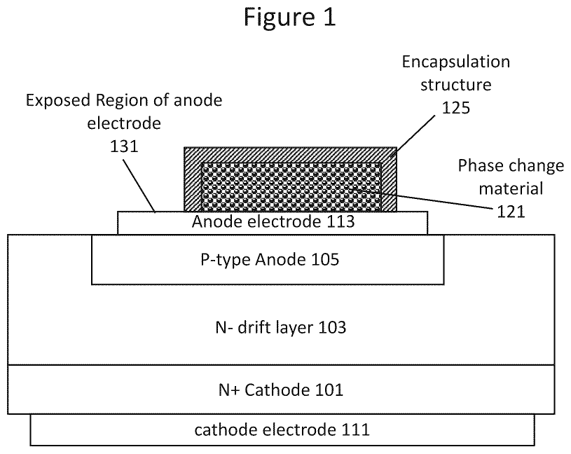

FIG. 1 is a cross-sectional view of a semiconductor electronic device including N+ cathode layer 101, N− drift layer 103, and p-type anode region 105 in/on a semiconductor electronic substrate to provide a diode or semiconductor electronic device according to some embodiments of inventive concepts. In addition, cathode electrode 111 is provided on N+ cathode 101, anode electrode 113 is provided on P-type anode 105, and phase-change material 121 is provided on anode electrode 113. Anode electrode 113 may include one or more of a metal, a metal alloy, a silicide, polysilicon, a metal oxide, solder, a solder alloy, a nanostructured metal (such as nanostructured silver), electroplated metal, electroless deposited metal, or another conductive material. Similarly, cathode electrode 111 may include on or more of a metal, a metal alloy, a silicide, polysilicon, a metal oxide, solder, a solder alloy, a nanostructured metal (such as nanostructured silver), electroplated metal, electroless deposited metal, or another conductive material.

Phase-change material 121 is a material that undergoes a phase-change (e.g., a solid-to-liquid phase-change or a solid-to-solid phase-change) at a phase-change temperature, and the phase-change material 121 is selected so that the phase-change temperature is less than a peak operating temperature of the semiconductor electronic device. Accordingly, when a temperature of the semiconductor electronic device reaches the phase-change temperature, phase-change material 121 undergoes the phase-change (e.g., from solid phase to liquid phase for a solid-to-liquid phase-change material, or from a first solid phase to a second solid phase for a solid-to-solid phase-change material) thereby absorbing thermal energy to reduce/delay further temperature increase of the semiconductor electronic device.

According to some embodiments, the phase-change material may have a phase-change temperature that is less than about 200 degrees C., and more particularly less than about 150 degrees C., and still more particularly, less than about 140 degrees C. Moreover, the phase-change material may be a solid-to-liquid phase-change material that undergoes a solid-to-liquid phase-change at the phase-change temperature, or the phase-change material may be a solid-to-solid phase-change material that undergoes a solid-to-solid phase-change at the phase-change temperature. If a solid-to-liquid phase-change material is used, the solid-to-liquid phase-change material may be/include an alloy including at least two of tin, bismuth, indium, lead, cadmium, and/or gallium, and more particularly, the phase-change material may be/include a Fields metal alloy including at least two of tin, bismuth, and/or indium. For example, a lead-free solder may be used having a melting temperature in the range of about 60 degrees C. to about 280 degrees C., and more particularly, in the range of about 60 degrees C. to about 110 degrees C. Solders used as phase-change materials may include: Bi, Au—Sn, Sn—37Pb, Sn—Ag—Cu, Sn—3.5Ag, Sn—0.7Ag, Sn—Bi—In, Sn—52In, Sn—58Bi, and In. Solders used as phase-change materials that can be electroplated may include: Bi, Au—Sn, Sn—37Pb, Sn—Ag—Cu, Sn—3.5Ag, Sn—0.7Ag, Sn—Bi—In, Sn—52In, Sn—58Bi, and In. Phase-change material may include polymers, salts, and other phase material known to those having skill in the art. If a solid-to-solid phase-change material is used, the solid-to-solid phase-change material may be/include an alloy including titanium and nickel, such as Nitinol.

When a solid-to-liquid phase-change material is used, encapsulation structure 125 may be provided to confine phase-change material 121 in the liquid phase whereby encapsulation structure 125 remains solid above the phase-change temperature and above the peak operating temperature of the semiconductor electronic device. Encapsulation structure 125 may be a metal structure, a nanostructured silver structure, a nanostructured material structure (e.g., a nanostructured silver structure), a polymer such as benzocyclobutene (BCB) or other polymer known to those skilled in the art, or other material structure. Encapsulation structure 125, for example, may be formed using electroless or electroplated metal deposition, chemical vapor deposition (CVD), dispensing of a polymer, spraying of a polymer, spin coating of a polymer, or other deposition techniques. In some embodiments, the encapsulation structure may be formed by electroless deposition of a metal such as nickel. In some embodiments, the electroless metal can be formed directly on a phase-change material 121 comprising a metal, metal alloy, or eutectic. In some embodiments, a seed layer such as a seed layer comprising silver may be formed on the surface of the phase--change material 121 comprising a polymer or salt prior to the electroless deposition of a metal or metal alloy encapsulation structure 125. In some embodiments, the encapsulation structure 125 may be formed using photolithography methods. In some embodiment, the encapsulation structure 125 may be deposited as a blanket deposition of a polymer or glass that encapsulates the surface of the semiconductor electronic device or substrate 547 either prior to or after forming an electrical contact to the semiconductor electronic device using an approach such as wire bonding, tab bonding, and/or flip-chip bonding. In some embodiments, the encapsulation structure may be formed by dispensing, jet dispensing, molding, or additive manufacturing. In some embodiment, the encapsulation structure may be formed by printing with a stencil. The encapsulation structure 125 may be electrically insulating or electrically conductive. In some, embodiments, the encapsulation structure 125 does not melt at the phase-change temperature. When a solid-to-solid phase-change material is used, encapsulation structure 125 may be omitted.

As further shown, exposed portion 131 of anode electrode 113 may be free of phase-change material 121 and/or encapsulation structure 125 to provide a surface for electrical connection. Accordingly, an electrical connection (e.g., a wire bond, a flip-chip solder bond, a wedge bond, etc.) may be electrically/mechanically coupled with exposed portion 131 of anode electrode 113.

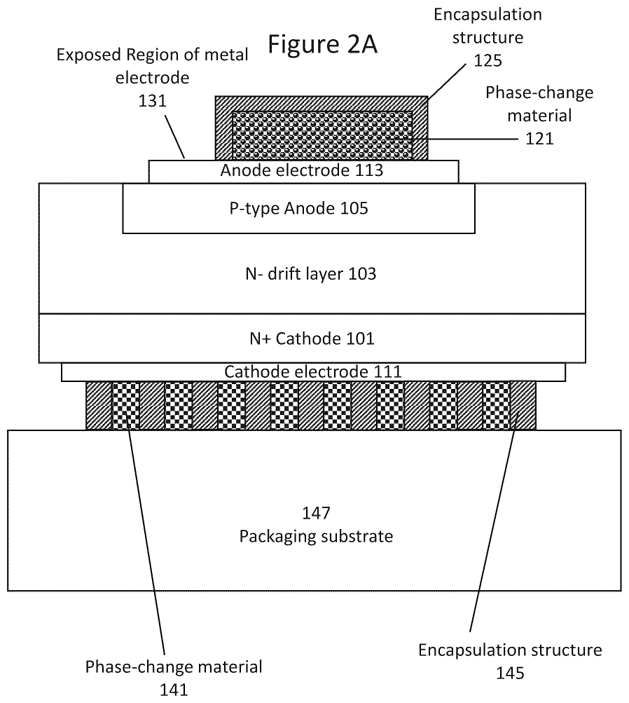

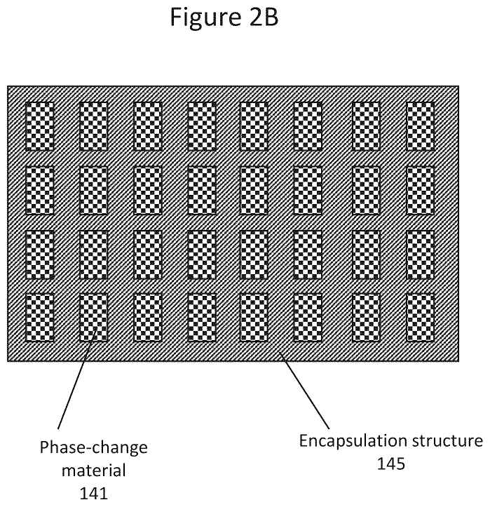

FIG. 2A is a cross-sectional view of a second semiconductor electronic device providing a diode or semiconductor electronic device according to some embodiments of inventive concepts. In FIG. 2A, N+ cathode layer 101, N− drift layer 103, p-type anode region 105, cathode electrode 111, anode electrode 113 (including exposed region 131), phase-change material 121, and encapsulation structure 125 may be provided as discussed above with respect to FIG. 1. In addition, cathode electrode 111 is mechanically, thermally, and electrically coupled with packaging substrate 147 through an interconnection structure including phase-change material 141 and encapsulation structure 145.

As shown, encapsulation structure 145 may have a matrix structure (also shown in the top view of FIG. 2B) providing a more secure mechanical connection with packaging substrate 147 and/or providing a more secure encapsulation of the phase-change material when the phase-change material 141 is in a liquid state. Moreover, phase-change material 141 and/or encapsulation structure 145 may be deposited or grown on cathode electrode 111, encapsulation structure 145 may be/include a high temperature solder and/or nanostructured silver, and phase-change material 141 may be/include a lower temperature phase-change material. For example, encapsulation structure 145 may be provided using materials discussed above with respect to encapsulation structure 125, and phase-change material 141 may be provided using materials discussed above with respect to phase-change material 121.

Packaging substrate 147 may be/include a metal substrate, a metal alloy substrate, a metal foil, a plated metal, a direct bond copper substrate, a copper/molybdenum/copper substrate, or other electrically/thermally conductive substrates.

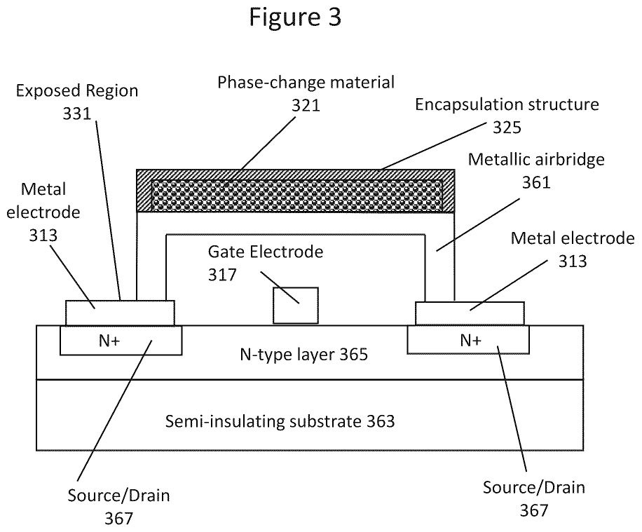

FIG. 3 is a cross-sectional view of a semiconductor electronic device including semi-insulating substrate 363, N-type layer 365, and N+ source/drain regions 367 according to some embodiments of inventive concepts. In FIG. 3, one or more of semi-insulating substrate 363, N-type layer 365, and N+ source/drain regions 367 may be provided in/on a semiconductor electronic substrate to provide a lateral transistor. In addition, electrodes 313 may be provided on respective N+ source/drain regions 367, metallic airbridge 361 may be provided on adjacent electrodes 313, and gate electrode 317 may be provided on n-type layer 365. Electrodes 313 and 317 may be provided using materials discussed above with respect to cathode and anode electrodes 111 and 113 of FIG. 1.

Airbridge 361 may be a metal/metallic bridge structure spanning two of electrodes 313 as shown in FIG. 3. According to some embodiments, a sacrificial layer may be formed between electrodes 313, airbridge 361 may be deposited on the sacrificial layer and electrodes 313, and the sacrificial layer may then be removed. According to some other embodiments, airbridge may be formed separately and then bonded to electrodes 313.

As shown in FIG. 3, phase-change material 321 is provided on airbridge 361, and phase-change material 321 may be provided using materials discussed above with respect to phase-change material 121 of FIG. 1. Accordingly, phase-change material 321 is thermally coupled with the semiconductor electronic device through airbridge 361, and a phase-change of phase-change material 321 can thus absorb thermal energy to reduce/delay temperature increase of the semiconductor electronic device.

As further shown, exposed portion 331 of electrode 313 may be free of airbridge 361 to provide a surface for electrical connection. Accordingly, an electrical connection (e.g., a wire bond, a flip-chip solder bond, a wedge bond, etc.) may be electrically/mechanically coupled with exposed portion 331 of electrode 313.

When a solid-to-liquid phase-change material is used, encapsulation structure 325 may be provided to confine phase-change material 321 in the liquid phase whereby encapsulation structure 325 remains solid above the phase-change temperature and above the peak operating temperature of the semiconductor electronic device. Encapsulation structure 325 may be provided using materials discussed above with respect to encapsulation structure 125 of FIG. 1. When a solid-to-solid phase-change material is used, encapsulation structure 325 may be omitted. Phase-change material 321 may be provided using materials discussed above with respect to phase-change material 121 of FIG. 1.

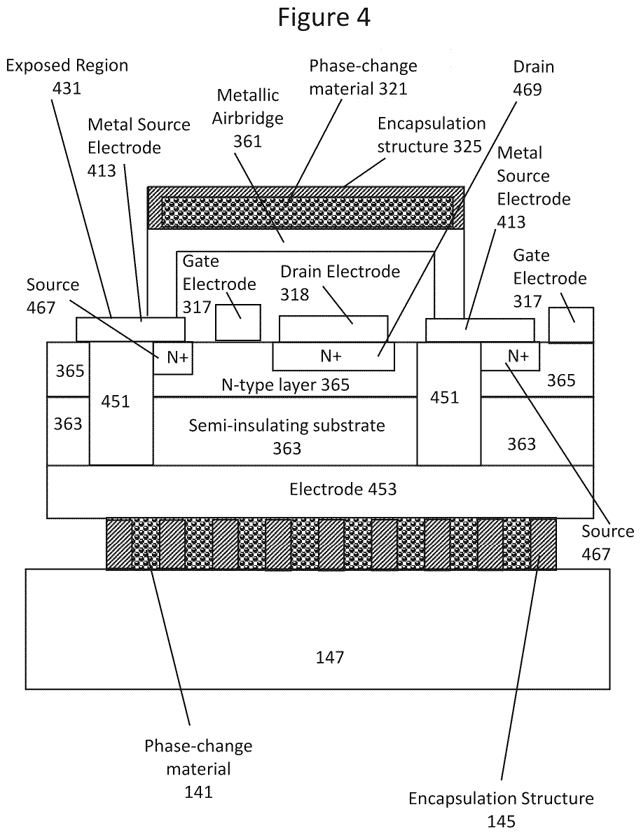

FIG. 4 is a cross-sectional view of a semiconductor electronic device including semi-insulating substrate 363, N-type layer 365, N+ drain region 469, and N+ source regions 467 according to some embodiments of inventive concepts. In FIG. 4, one or more of semi-insulating substrate 363, N-type layer 365, N+ drain region 469, and N+ source regions 467 may be provided in/on a semiconductor electronic substrate to provide a lateral transistor. As shown, metal source electrodes 413 may be provided on respective N+source regions 467, metallic airbridge 361 may be provided on adjacent source electrodes 413, gate electrode 317 may be provided on a channel region between source/drain regions 467/469, and drain electrode 318 may be provided on N+ drain region 469. Electrodes 317, 318, and 413 may be provided using materials discussed above with respect to cathode and anode electrodes 111 and 113 of FIG. 1.

Airbridge 361 may be a metal/metallic bridge structure spanning two of electrodes 413 as shown in FIG. 4. According to some embodiments, a sacrificial layer may be formed between source electrodes 413, airbridge 361 may be deposited on the sacrificial layer and source electrodes 413, and the sacrificial layer may be removed. According to some other embodiments, airbridge may be formed separately and then bonded to source electrodes 413.

As shown in FIG. 4, phase-change material 321 is provided on airbridge 361, and phase-change material 321 may be provided using materials discussed above with respect to phase-change material 121 of FIG. 1. Accordingly, phase-change material 321 is thermally coupled with the semiconductor electronic device through airbridge 361, and a phase-change of phase-change material 321 can thus absorb thermal energy to reduce/delay temperature increase of the semiconductor electronic device.

As further shown, exposed portion 431 of electrode 413 may be free of airbridge 361 to provide a surface for electrical connection. Accordingly, an electrical connection (e.g., a wire bond, a flip-chip solder bond, a wedge bond, etc.) may be electrically/mechanically coupled with exposed portion 431 of electrode 413.

When a solid-to-liquid phase-change material is used, encapsulation structure 325 may be provided to confine phase-change material 321 in the liquid phase whereby encapsulation structure 325 remains solid above the phase-change temperature and/or above the peak operating temperature of the semiconductor electronic device. Encapsulation structure 325 may be provided using materials discussed above with respect to encapsulation structure 125 of FIG. 1. When a solid-to-solid phase-change material is used, encapsulation structure 325 may be omitted.

FIG. 4 further illustrates through substrate metal filled source vias 451 providing electrical coupling between source electrodes 431 and metallic ground plane or source metal electrode 453 on a back side of the device. If vias 451 and electrode 453 are provided according to some embodiments, exposed regions 431 of source electrodes 413 may be omitted.

In addition, electrode 453 may be mechanically, thermally, and electrically coupled with packaging substrate 147 through an interconnection structure including phase-change material 141 and encapsulation structure 145 as discussed above with respect to FIGS. 2A and 2B.

According to some other embodiments of FIG. 4, vias 451 may be omitted with electrical coupling (e.g., wire/solder bonding) provided to exposed regions of electrodes 413. In such embodiments, a backside layer 453 (also referred to as a backside electrode or ground plane) may provide mechanical and thermal coupling between the semiconductor electronic substrate and phase-change material 141 without providing electrical coupling between any of the front side electrodes and packaging substrate 147.

Backside layer 453 may have a thermal conductivity of at least about 30 W/mK, and more particularly, greater than about 35 W/mK. For example, backside layer 453 may include at least one of a metal, metal alloy, silicon, polysilicon, boron nitride, solder, diamond, aluminum nitride, and/or carbon graphene.

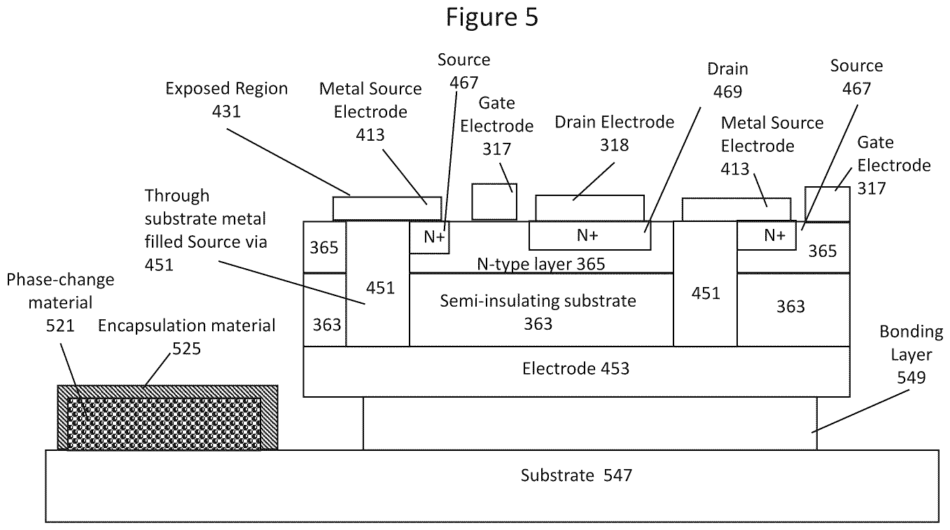

FIG. 5 is a cross-sectional view of a semiconductor electronic device including semi-insulating substrate 363, N-type layer 365, N+ drain region 469, N+ source regions 467, source electrodes 413, drain electrode 318, gate electrode 317, conductive vias 451, and metallic ground plane or source metal electrode 453 as discussed above with respect to FIG. 4. Electrodes 317, 318, and 413 may be provided using materials discussed above with respect to cathode and anode electrodes 111 and 113 of FIG. 1.

In FIG. 5, metallic ground plane or source metal electrode 453 may be electrically, mechanically, and thermally coupled with packaging substrate 547 using bonding layer 549. Bonding layer 549 may be a solder, a nanostructure silver layer, or thermal interface material known to those skilled in the art used to bond the semiconductor electronic device to packaging substrate 547. Packaging substrate 547 may be an interposer such as an interposer for 2.5D integrated circuit technology. The interposer packaging substrate 547 may be silicon or glass. Packaging substrate may have through substrate vias for improved thermal conduction or electric signal propagation. In some embodiments, packaging substrate 547 may be electrically conductive or insulating. The through substrate via for electrically conducting package substrate 547 may have a dielectric layer on the sidewalls of the through substrate via to isolate the electrical signal in the through substrate via from the electrically conducting package substrate 547. Packaging substrate 547 may have through silicon via that has a dielectric insulating layer on the side walls of the through silicon via and is filled with copper. Package substrate 547 may be a metal flange. Package substrate 547 may be a Printed Circuit Board (PCB) with metal interconnects and metal regions on the surface. Packaging substrate may be provided as discussed above with respect to packaging substrate 147 of FIGS. 2A and 4.

As further shown in FIG. 5, phase-change material 521 may be provided on packaging substrate 547 such that phase-change material 521 is laterally spaced apart from the semiconductor electronic device. Accordingly, phase-change material 521 is thermally coupled with the semiconductor electronic device through packaging substrate 547 and bonding layer 549. As shown in FIG. 5, phase-change material 521 and the semiconductor electronic device may be provided on a same side of packaging substrate 547. According to some other embodiments of inventive concepts, phase-change material 525 and the semiconductor electronic device may be provided on opposite sides of packaging substrate 547, and if provided on opposite sides of packaging substrate 547, phase-change material 525 may be laterally spaced apart from the semiconductor electronic device, or phase-change material 525 may be aligned with the semiconductor electronic device.

Moreover, phase-change material 521 may be provided as discussed above with respect to phase-change material 121 of FIG. 1 or 2A, and/or phase-change material 321 of FIG. 3 or 4; and encapsulation structure 525 may be provided as discussed above with respect to encapsulation structure 125 of FIG. 1 or 2A, and/or encapsulation structure 325 of FIG. 3 or 4. Accordingly, phase-change material 521 may be a solid-to-liquid phase-change material or a solid-to-solid phase-change material. If phase-change material 521 is a solid-to-solid phase-change material, encapsulation structure 521 may be omitted.

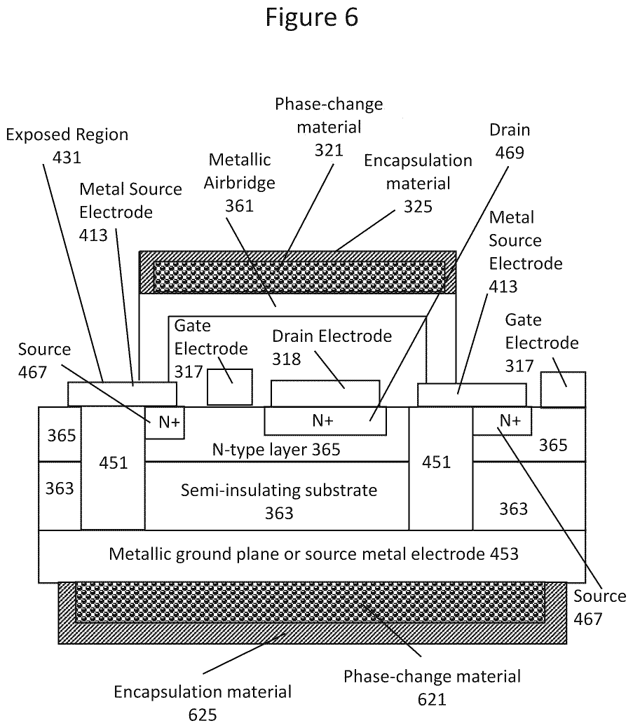

FIG. 6 is a cross-sectional view of a semiconductor electronic device including semi-insulating substrate 363, N-type layer 365, N+ drain region 469, N+ source regions 467, source electrodes 413, drain electrode 318, gate electrode 317, conductive vias 451, metallic airbridge 361, phase-change material 361, encapsulation structure 325, and metallic ground plane or source metal electrode 453 as discussed above with respect to FIG. 4. Electrodes 317, 318, and 413 may be provided using materials discussed above with respect to cathode and anode electrodes 111 and 113 of FIG. 1.

In addition, phase-change material 621 and encapsulation structure 625 may be provided on metallic ground plane or source metal electrode 453 without an intervening packaging substrate. Phase-change material 621 and/or encapsulation structure 625 may be provided using materials discussed above, for example, with respect phase-change material 121 and encapsulation structure 125 of FIG. 1.

According to some embodiments of inventive concepts discussed above, one or more metallic materials may be provided between the phase-change material and an electrode (e.g., a source electrode, a drain electrode, an anode electrode, a cathode electrode, a base electrode, an emitter electrode, and/or a gate electrode) of the electronic device.

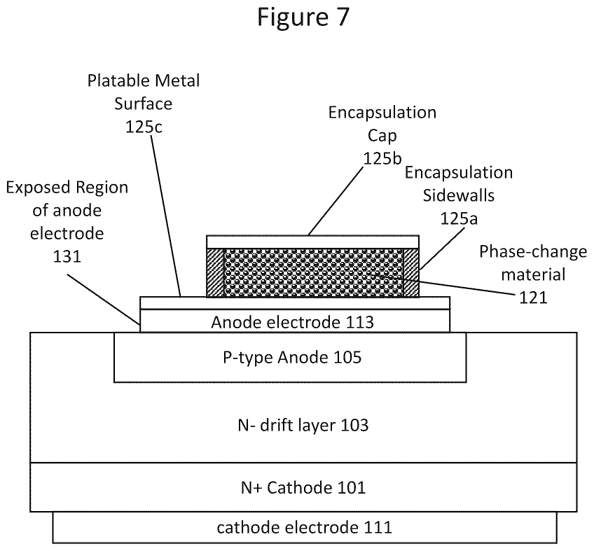

FIG. 7 is a cross-sectional view of a semiconductor electronic device including cathode electrode 111, N+ cathode 101, N− drift layer 103, p-type anode 105, and anode electrode 113 as discussed above with respect to FIG. 1. In addition, the device of FIG. 7 includes platable metal surface 125c, phase-change material 121, encapsulation sidewalls 125a, and encapsulation cap 125b. More particularly, encapsulation sidewalls 125a may be provided using a high temperature, thick photo-definable (also referred to as photosensitive) polymer photoresist such as SU8 (a permanent photoresist), and encapsulation cap 125b may be provided using a polymer or inorganic cap material. Encapsulation sidewalls 125a may thus be electrically insulating. In some embodiments, the phase-change material 121 may be as thick as the encapsulation sidewalls 125a. In some embodiments, the phase-change material 121 may have a thickness that is less than the thickness of the encapsulation sidewalls 125a. In some embodiments, the phase-change material 121 may be thicker than the encapsulation sidewalls 125a. In some embodiments, the encapsulation sidewalls 125a may be electrically conductive. In some embodiment, encapsulating side wall 125a may be provided by electroplating nickel, gold, or a solder with a melting temperature higher than the melting temperature of the phase-change material 121 melting temperature. Encapsulating sidewalls 125a may be provided by an additive manufacturing tool, a dispensing tool, or a jet dispensing tool that can dispense materials such as polymer, glass frit, or solder with a melting temperature higher than the phase-change material 121 melting temperature. If anode electrode 113 is sufficiently platable, a separate layer providing platable metal surface may be omitted. If anode electrode 113 is not sufficiently platable, however, a metal layer may be provided to provide a platable metal surface 125c on which phase-change material 121 can be plated. A UV sensitive polymer photoresist such as SU8 may be used to form encapsulation sidewalls 125a having a height of up to 150 μm to support plating of phase-change material 121 having a thickness up to 150 μm. According to some other embodiments, an x-ray sensitive polymer photoresist, such as Poly(methyl methacrylate) or PMMA, may be used to form encapsulation sidewalls 125a having a height of up to 1 mm to support plating of phase-change material 121 having a thickness up to 1 mm.

In particular, polymer encapsulation sidewalls 125a may be formed on platable metal surface 125c. For example, a continuous layer of the polymer may be formed on (and beyond) platable metal surface 125c and then patterned using photolithography to provide encapsulation sidewalls 125a. Phase-change material may then be plated (e.g., electroplated) on exposed portions of platable metal surface 125c between encapsulation sidewalls 125a to provide phase-change material 121. Once phase-change material 121 has been plated, encapsulation cap 125b may be formed on phase-change material 121 and encapsulation sidewalls 125a. Accordingly, encapsulation sidewalls 125a and encapsulation cap 125b may serve the same purpose as encapsulation structure 125 of FIG. 1, that is, to encapsulate phase-change material 121 when heated to the liquid phase. Accordingly, encapsulation sidewalls 125a and encapsulation cap 125b are maintained in a solid state above the phase-change temperature of phase-change material 121 and above a maximum operating temperature of the electronic device.

In addition, the structure of FIG. 7 may facilitate a wafer scale approach to simultaneously provide the phase-change material for a plurality of devices (e.g., semiconductor electronic devices) fabricated on the wafer. For example, a plurality of the semiconductor electronic devices of FIG. 7 may be simultaneously fabricated on a single wafer, and phase-change material and encapsulation structures can be provided for all the semiconductor electronic devices before separating the semiconductor electronic devices from the wafer. In such embodiments, a continuous layer of the metal providing the platable metal surface 125c may be provided across the wafer including the plurality of semiconductor electronic device and respective anode electrodes. Encapsulation sidewalls 125a may be formed on the respective anodes 113, and phase-change material 121 may be electroplated on the respective anode electrodes between respective encapsulation sidewalls. After plating, encapsulation caps 125b may be formed on the resulting phase-change material, and excess portions of the metal layer providing platable metal surface may be removed to reduce/avoid shorting anode electrodes to N− drift layer. Once excess portions of the metal layer providing platable metal surface 125c have been removed and encapsulation caps have been formed, individual semiconductor electronic devices may be separated from the wafer.

In addition, the structure of FIG. 7 may increase the volume of the phase-change material 121 and may reduce the effective thermal expansion coefficient difference between the phase-change material 121 and the semiconductor material or substrate 105, 103, and 101. In some embodiments, the phase-change material 121 may be thicker than the encapsulation sidewalls 125a. The phase-change material 121 may expand to have a larger lateral dimension than the inner surfaces of the encapsulation sidewall material 125 for embodiments with the phase-change material 121 having a greater thickness than the encapsulations sidewalls 125a, and the phase-change material 121 may thus have a mushroom shape. The volume of phase-change material can be increased for embodiments in which the phase-change material is thicker than the encapsulation sidewall 125a. The effective thermal expansion coefficient difference between the phase-change material 121 and the semiconductor material or semiconductor substrate 105, 103, and 101 can be reduced by having multiple phase-change material regions 121 and multiple encapsulation sidewall regions 125a. By having multiple phase-change material regions 121 with a smaller lateral dimension than a single phase-change material region 121 with a large lateral dimension, there is less phase-change material in contact with the semiconductor substrate 105, 103, and 101 per micron of lateral dimension and there will be less strain on the semiconductor substrate 105, 103, and 101. The lateral dimension of the phase-change material region 121 can be in the range of 0.1 micron to 10 mm. In some embodiments, the height of the encapsulation sidewall material 125a can be in the range of 2 microns to 250 microns. The phase-change material 121 can have a thickness above the encapsulation side walls 125a in the range of 0.1 micron to 300 microns. In some embodiments, the mushroom shape of the phase-change material 121 above the sidewall encapsulation structure 125a can merge to form a continuous phase material 121 structure above the encapsulation sidewalls 125a.

In addition, the structure of FIG. 7 includes an encapsulation cap 125. Encapsulation cap 125b, for example, may be formed using electroless or electroplated metal deposition, chemical vapor deposition (CVD), dispensing of a polymer, spraying of a polymer, spin coating of a polymer, or other deposition techniques known to those skilled in the art. In some embodiments, the encapsulation cap 125b may be formed by electroless deposition of a metal such as nickel. In some embodiments, the electroless metal can be formed directly on a phase-change material 121 comprising a metal, metal alloy, or eutectic. In some embodiments, a seed layer such as a seed layer comprising silver may be formed on the surface of the phase-change material 121 comprising a polymer or salt prior to the electroless deposition of a metal or metal alloy encapsulation cap 125b. In some embodiments, the encapsulation cap 125b may be formed using photolithography methods. In some embodiment, the encapsulation cap 125b may be deposited as a blanket deposition of a polymer or glass that encapsulates the surface of the semiconductor electronic device or substrate 547 either prior to or after forming an electrical contact to the semiconductor electronic device using an approach such as wire bonding, tab bonding, and/or flip-chip bonding. In some embodiments, the encapsulation cap 125b may be formed by spraying, dispensing, jet dispensing, molding, or additive manufacturing. In some embodiment, the encapsulation structure may be formed by printing with a stencil. The encapsulation cap 125b may be electrically insulating or electrically conductive. In some, embodiments, the encapsulation cap 125b does not melt at the phase-change temperature.

According to some embodiments, encapsulation sidewalls 125a may provide a plating mask used to plate (e.g., using electroplating and/or electroless plating) phase-change material 121. For example, encapsulation sidewalls 125a may cover all portions of platable metal surface on which phase-change materials 121 will not be plated. According to some embodiments, encapsulation sidewalls 125a may be omitted. For example, phase-change material 121 may be formed (e.g., by plating), and then encapsulation cap 125b may be formed the top and sidewalls of phase-change material 121 (e.g., by plating). Accordingly, encapsulation sidewalls 125a may be optional.

The encapsulation sidewall 125a, encapsulation cap 125b, and the phase chance material 121 discussed above with respect to FIG. 7 may be used for the embodiments shown in FIGS. 1, 2, 3, 4, 5, and/or 6.

By integrating a phase-change material (e.g., a solid-to-liquid phase-change material) with an electronic device, thermal buffering may be provided to reduce/limit peak temperatures experienced by the electronic device. Accordingly, the electronic device may be able to produce higher levels of output power and/or operate with improved reliability.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. The term “and/or” includes any and all combinations of one or more of the associated listed items.

Spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present inventive concepts.

It will also be understood that when an element is referred to as being on or connected to/with or coupled to/with another element, it can be directly on or connected to/with or coupled to/with the other element, or intervening elements may be present. In contrast, when an element is referred to as being directly on or directly connected to/with or directly coupled to/with another element, there are no intervening elements present. Moreover, if an element is referred to as being “on” another element, no spatial orientation is implied such that the element can be over the other element, under the other element, on a side of the other element, etc.

Embodiments are described herein with reference to cross-sectional and/or perspective illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted/diffused region (also referred to as doped regions) illustrated as a rectangle will, typically, have rounded or curved features and/or a gradient of implant/diffusion concentration at its edges rather than a binary change from implanted to non-implanted region. Likewise, a buried region formed by implantation/diffusion may result in some implantation/diffusion in the region between the buried region and the surface through which the implantation/diffusion takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which the inventive concepts herein belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

While inventive concepts have been particularly shown and described with reference to examples of embodiments thereof, it will be understood that various changes in form and details may be made therein without departing from the spirit of the following claims.

1. An electronic device comprising:
a semiconductor electronic substrate; and
a phase-change material thermally and mechanically coupled with the semiconductor electronic substrate, wherein the phase-change material undergoes a phase-change at a phase-change temperature for the phase-change material, and wherein the phase-change temperature is less than a peak operating temperature of the electronic device.

2. The electronic device of claim 1, wherein the phase-change temperature is less than about 150 degrees C.

3. The electronic device of claim 1, wherein the phase-change material undergoes a solid-to-liquid phase-change at the phase-change temperature.

4. The electronic device of claim 3, wherein the phase-change material comprises an alloy including at least two of tin, bismuth, indium, lead, cadmium, and/or gallium.

5. The electronic device of claim 4, wherein the phase-change material comprises a Fields metal alloy including at least two of tin, bismuth, and/or indium.

6. The electronic device of claim 1, wherein the phase-change material undergoes a solid-to-solid phase-change at the phase-change temperature.

7. The electronic device of claim 6, wherein the phase-change material comprises an alloy including titanium and nickel.

8. The electronic device of claim 7, wherein the alloy comprises Nitinol.

9. The electronic device of claim 1 further comprising:
an encapsulation structure on the phase-change material, wherein the encapsulation structure maintains a solid phase over a range of temperatures including the phase-change temperature of the phase-change material and the peak operating temperature of the electronic device.

10. The electronic device of claim 9, wherein the encapsulation structure comprises at least one of copper, nickel, a high temperature solder, a nanostructured material, and/or nanostructured silver.

11. The electronic device of claim 10, wherein the encapsulation structure comprises a high temperature solder including tin and at least one of gold, nickel, zinc, copper, and/or silver.

12. The electronic device of claim 1 further comprising:
an electrode on the semiconductor electronic substrate, wherein the phase-change material is thermally and mechanically coupled with semiconductor electronic substrate through the electrode.

13. The electronic device of claim 12, wherein the electrode comprises at least one of a gate electrode, a source electrode, a drain electrode, a base electrode, an emitter electrode, a collector electrode, an anode electrode, a cathode electrode, and/or a back side electrode.

14. The electronic device of claim 12, further comprising:
an airbridge mechanically coupled between the electrode and the phase-change material, so that the phase-change material is thermally and mechanically coupled with the electrode through the airbridge.

15. The electronic device of claim 12, wherein the phase-change material is on a first portion of the electrode, and wherein a second portion of the electrode is free of the phase-change material, the electronic device further comprising:
an electrical connection mechanically coupled with the second portion of the electrode.

16. The electronic device of claim 15, wherein the electrical connection comprises at least one of a wire bond, a solder bond, and/or a wedge bond.

17. The electronic device of claim 1 further comprising:
a packaging substrate on the phase-change material, wherein the phase-change material is mechanically coupled between the semiconductor electronic substrate and the packaging substrate.

18. The electronic device of claim 1 further comprising:
a packaging substrate mechanically and thermally coupled with the semiconductor electronic substrate;
wherein the phase-change material is thermally and mechanically coupled with the semiconductor electronic substrate through the packaging substrate.

19. The electronic device of claim 1, wherein the semiconductor electronic substrate comprises a semiconductor electronic device including at least one of a diode, a transistor, a field effect transistor (FET), a bipolar transistor, an insulated gate bipolar transistor, a thyristor, a power switch, a PiN diode, a microwave device, a radio frequency (RF) device, a silicon controlled rectifier (SCR), CMOS circuitry, and/or an integrated circuit device.

20. The electronic device of claim 1, wherein the semiconductor electronic substrate has opposing front and back sides, wherein the semiconductor electronic substrate includes a lateral semiconductor device on the front side, the electronic device further comprising:
a plurality of electrodes on the front side of the semiconductor electronic substrate;
wherein the phase-change material is mechanically and thermally coupled with the back side of the semiconductor electronic substrate so that the semiconductor electronic substrate is thermally coupled between the phase-change material and the plurality of electrodes.

21. The electronic device of claim 1, wherein the phase-change material is thermally and mechanically coupled with the semiconductor electronic substrate using a material having a thermal conductivity of at least about 30 W/mK.

22. The electronic device of claim 21, wherein the material having the thermal conductivity of at least about 30 W/mK comprises at least one of a metal, metal alloy, silicon, polysilicon, boron nitride, solder, diamond, aluminum nitride, and/or carbon graphene.

23. The electronic device of claim 1 further comprising:
an encapsulation structure including a polymer sidewall on the semiconductor electronic substrate surrounding the phase-change material and an encapsulation cap on the phase-change material and on the polymer sidewall such that the phase-change material is between the semiconductor electronic substrate and the encapsulation cap.

24. The electronic device of claim 23, wherein the encapsulation cap comprises at least one of a polymer and/or an inorganic material.

25. The electronic device of claim 23, wherein the polymer sidewall comprises a photosensitive polymer sidewall.

26. The electronic device of claim 25, wherein the polymer sidewall comprises at least one of a ultraviolet (UV) sensitive polymer and/or a x-ray sensitive polymer.
